(19) United States
(12) Patent Application Publication
(10) Pub. No.: US 2024/0313099 A1
(43) Pub. Date: Sep. 19, 2024

(54) METAL STACK WITH PHONON SCATTERING LAYER THAT FORMS A NON-OHMIC CONTACT TO A SEMICONDUCTOR LAYER

(71) Applicant: Wolfspeed, Inc., Durham, NC (US)

(72) Inventors: Kyle Bothe, Cary, NC (US); Evan Jones, Durham, NC (US); Daniel Etter, Durham, NC (US)

(21) Appl. No.: 18/121,782

(22) Filed: Mar. 15, 2023

(51) Int. Cl. H01L 29/778; H01L 29/20; H01L 29/423; H01L 29/872

(52) U.S. Cl. CPC H01L 29/7786; H01L 29/2003; H01L 29/4232; H01L 29/872

(57) ABSTRACT

A transistor device includes a semiconductor body and a non-ohmic contact on the semiconductor body. The non-ohmic contact includes a phonon scattering layer on the semiconductor body, a protection layer on a surface of the phonon scattering layer opposite the semiconductor body, and a contact layer on a surface of the protection layer opposite the phonon scattering layer. The phonon scattering layer has a work function in a range of about 4.5 eV to about 5.7 eV and a melting point in a range of about 1550° C. to about 3200° C.

### TECHNICAL FIELD

The present disclosure relates to a semiconductor devices, and in particular to semiconductor devices including non-ohmic contacts, such as Schottky contacts.

### BACKGROUND

Semiconductor devices, such as high electron mobility transistors (HEMTs), Schottky diodes, metal semiconductor field effect transistors (MESFETS) and the like employ a non-ohmic contacts to semiconductor layers. A contact that forms a Schottky barrier junction, referred to as a Schottky contact, is an example of a non-ohmic contact. Schottky contacts are generally metal contacts that are formed on a semiconductor material to create a metal-semiconductor junction that tends to provide a rectifying effect due to an inherent potential barrier that is formed at the metal-semiconductor junction. That is, current can flow through a Schottky junction when the junction is forward biased by applying a positive voltage from the metal to the semiconductor. Under reverse bias conditions in which a negative voltage is applied from the metal to the semiconductor, the Schottky junction blocks current flow except for a small leakage current.

A non-ohmic contact may be created by forming one or more metal layers on a surface of a semiconductor body. For example, a gate contact for a HEMT may be formed as a non-ohmic contact on the semiconductor body and between corresponding source and drain contacts. If the semiconductor material on which the HEMT's gate contact is formed includes aluminum gallium nitride (AlGaN), two common metals that are often used in the gate contact of the HEMT are nickel (Ni) and gold (Au).

More specifically, a Ni layer is typically formed on the semiconductor body of the HEMT, and an Au layer is formed on the Ni layer. Other layers may be provided between the Ni and Au layers. The Ni layer may form a Schottky barrier junction to the semiconductor body, and thus may be referred to as a “Schottky layer.” Notably, Ni is often used for the Schottky layer of a Schottky contact to an AlGaN material due to the relatively high barrier height provided between Ni and AlGaN. An upper Au layer may be formed at or near the top of the gate contact to provide a contact layer. The use of Au for the contact layer may help to reduce a resistance of the gate contact.

### SUMMARY

A transistor device according to some embodiments includes a semiconductor body and a non-ohmic contact on the semiconductor body. The non-ohmic contact includes a phonon scattering layer on the semiconductor body, a protection layer on a surface of the phonon scattering layer opposite the semiconductor body, and a contact layer on a surface of the protection layer opposite the phonon scattering layer. The phonon scattering layer has a work function in a range of about 4.5 eV to about 5.7 eV and a melting point in a range of about 1550° C. to about 3200° C.

The phonon scattering layer may include ruthenium (Ru). In some embodiments, the phonon scattering layer may include at least one of rhenium (Re), rhodium (Rh), niobium (Nb), palladium (Pd), osmium (Os), or iridium (Ir).

A thickness of the phonon scattering layer may be in a range of about 5 nm to about 35 nm, a thickness of the protection layer may be in a range of about 5 nm to about 40 nm, and a thickness of the contact layer may be greater than about 100 nm.

In some embodiments, a ratio of a first thickness of the phonon scattering layer to a second thickness of the protection layer may be about 1:1, in some embodiments about to 1:2, and in some embodiments about 1:3.

In some embodiments, a thickness of the phonon scattering layer may be in a range of about 5 nm to about 35 nm, a thickness of the protection layer may be in a range of about 5 nm to about 40 nm, and a thickness of the contact layer may be greater than about 100 nm.

The semiconductor body may include one or more Group III nitride epitaxial layers. The one or more Group III nitride epitaxial layers may include at least one of a gallium nitride layer and an aluminum gallium nitride layer.

The transistor device may further include a silicon carbide substrate, where the semiconductor body is on a surface of the silicon carbide substrate.

The transistor device may include a gallium nitride (GaN) based high-electron mobility transistor (HEMT).

In some embodiments, the protection layer may include titanium (Ti) and the contact layer may include gold (Au).

The non-ohmic contact may form a Schottky junction with the semiconductor body.

A transistor device according to some embodiments includes a semiconductor body, a gate electrode, a source electrode, and a drain electrode on the semiconductor body, and a metal stack between the semiconductor body and at least a portion of the gate electrode. The metal stack includes a layer of ruthenium (Ru) on the semiconductor body, a protection layer on a surface of the layer of ruthenium (Ru) opposite the semiconductor body, a diffusion barrier layer on the surface of the protection layer opposite the layer of ruthenium (Ru), and a contact layer on the surface of the diffusion barrier layer opposite the protection layer.

A thickness of the layer of ruthenium (Ru) may be in a range of about 5 nm to 35 nm. A thickness of the protection layer may be in a range of about 5 nm to about 20 nm. A thickness of the diffusion barrier layer may be in a range of about 5 nm to about 20 nm. A thickness of the contact layer may be greater than about 100 nm.

In some embodiments, the protection layer may include a first protection layer and a second protection layer, and a thickness of the layer of ruthenium (Ru) may be about 5 nm, a thickness of the first protection layer may be about 15 nm, a thickness of the second protection layer may be about 10 nm, a thickness of the diffusion barrier layer may be about 20 nm, and a thickness of the contact layer may be greater than 100 nm. The first protection layer may include Ti, and the second protection layer may include Pt.

The semiconductor body may include one or more Group III nitride epitaxial layers. The one or more Group Ill nitride epitaxial layers may include at least one of a gallium nitride layer and an aluminum gallium nitride layer.

The transistor device may further include a silicon carbide substrate, where the semiconductor body is on a surface of the silicon carbide substrate.

The transistor device may include a gallium-nitride (GaN) based high-electron mobility transistor HEMT.

The protection layer may include titanium (Ti), the diffusion barrier layer may include platinum (Pt) and the contact layer may include gold (Au).

### BRIEF DESCRIPTION OF THE DRAWINGS

FIG. 1 is a simplified cross-section of an exemplary high electron mobility transistor on which a metal stack according to some embodiments may be employed.

FIG. 2 illustrates a gate contact according to some embodiments.

FIGS. 3A and 3B illustrate gate contacts according to further embodiments.

FIG. 4A illustrates the current characteristics as a function of forward voltage of a Schottky diode contact formed according to some embodiments.

FIG. 4B illustrates capacitance values as a function of forward voltage of a Schottky diode contact formed according to some embodiments.

FIG. 5 is a graph of Schottky barrier height of a contact formed as described above at various process temperatures.

FIG. 6 illustrates reverse leakage current of a contact according to some embodiments compared to reverse leakage current of a conventional Ni-based contact.

FIG. 7 illustrates an analysis of a plurality of conventional contacts and a plurality of contacts according to embodiments described herein.

FIGS. 8A-8C are schematic block diagrams of multi-amplifier circuits in which RF transistor amplifiers incorporating transistor devices according to embodiments may be used.

FIG. 9 is a schematic plan view of a monolithic microwave integrated circuit RF transistor amplifier according to some embodiments.

FIGS. 10A and 10B are schematic cross-sectional views illustrating two example ways that an RF transistor device according to some embodiments may be packaged to provide RF transistor amplifiers.

### DETAILED DESCRIPTION OF EMBODIMENTS

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

As discussed above, a non-ohmic contact, such as a Schottky contact, may be created by forming one or more metal layers on a surface of a semiconductor body where the contact is desired. One problem with forming non-ohmic contacts on a semiconductor body is that the overall process for fabricating a semiconductor device may expose the contact to high temperatures, which can degrade the performance of the contact in terms of its ability to block leakage current. Some embodiments described herein are based on a realization that it may be desirable, in a metal stack for a semiconductor device, to provide a phonon-scattering layer as the layer of the metal stack that contacts the semiconductor body. For a Schottky contact, this means that the layer that forms a Schottky junction with the semiconductor body functions as both a Schottky contact and as an effective phonon-scattering layer. As known in the art, a phonon is a quasiparticle that describes a quantum of vibrational motion in a lattice of atoms or molecules, such as a semiconductor crystal. Phonons carry thermal energy through a lattice through vibrational energy. Thus, the propensity of a layer to scatter phonons may help make the layer less susceptible to heat generated by semiconductor manufacturing processes.

A particular metal that can form a Schottky junction to wide bandgap materials, such as silicon carbide and Group III-nitride materials, and that can also function as a phonon scattering layer, is ruthenium (Ru). As a phonon-scattering material, ruthenium is resistant to heat, and has a melting point above 2600 K. Moreover, as a member of the platinum group of metals, ruthenium is also resistant to chemical attacks, corrosion and oxidation, especially when compared to nickel, which is commonly used to form Schottky contacts to wide bandgap semiconductors. Ruthenium is also wear-resistant, and may also function as a diffusion barrier layer. By providing a ruthenium layer in a metal stack, it may also be possible to omit a separate diffusion barrier layer, such as platinum, from the metal stack.

Ruthenium has a work function of about 4.7 eV, which allows it to form a Schottky barrier junction with wide bandgap materials, such as silicon carbide and Group III-nitride materials. Additionally, as ruthenium has a melting point greater than 2600K, it is highly thermally stable. This may reduce the occurrence of diffusion of ruthenium atoms into the semiconductor body, which can degrade the semiconductor device.

As is known in the art, the platinum-group metals include ruthenium, rhodium, palladium, osmium, iridium, and platinum. These six noble, precious metallic elements are clustered together in the periodic table. These elements are all transition metals in the d-block (groups 8, 9, and 10, periods 5 and 6) of the periodic table. Because the platinum-group metals share similar material characteristics, other platinum-group metals may be used in addition to or instead of ruthenium according to some embodiments. In particular, the phonon scattering layer may include rhodium, palladium, osmium, and/or iridium. Other similar metals, such as rhenium and niobium, may also suitably function as, or be included in, phonon-scattering layers in some embodiments. In some embodiments, the phonon scattering layer may be an alloy of two or more of these metals.

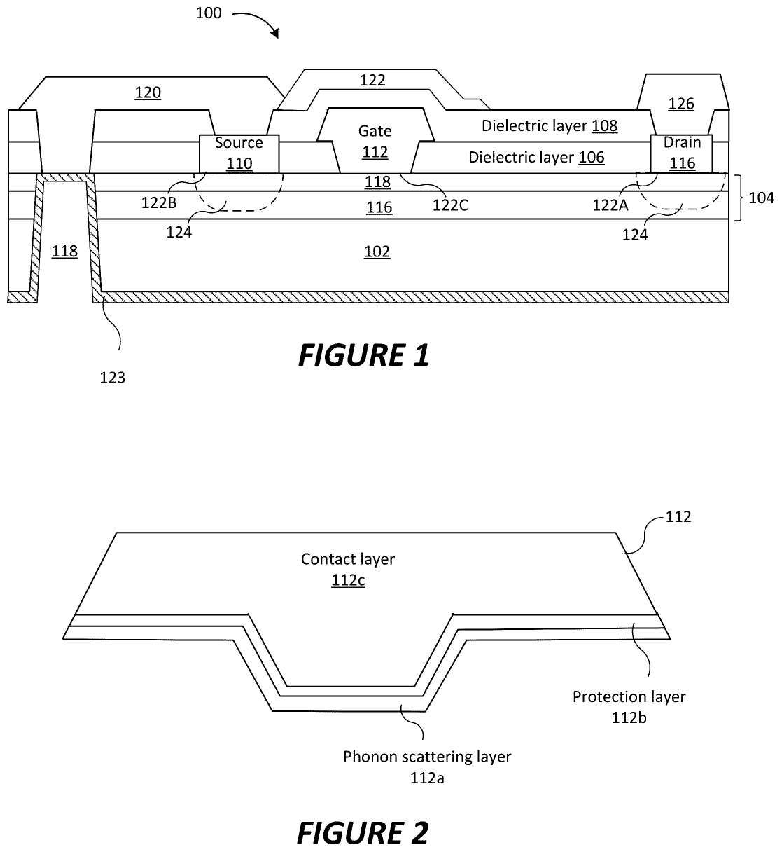

A simplified cross-section of an exemplary high electron mobility transistor (HEMT) 100 on which a metal stack according to some embodiments may be employed is shown in FIG. 1. Note, however, that those skilled in the art will recognize the applicability to the concepts of the present disclosure for various semiconductor devices and, in particular, other radio frequency (RF) and/or power devices such as, for example, Schottky diodes, metal semiconductor field effect transistors (MESFETs), gallium nitride (GaN) based power switches, and the like.

In the illustrated example, the HEMT 100 is formed in a semiconductor body 104 comprising a Group III nitride material system on a substrate 102. In particular, the HEMT 100 is formed in a GaN/aluminum gallium nitride (AlGaN) material system, and the substrate 102 is formed of silicon carbide (SiC). The substrate 102 is a semi-insulating substrate formed of a 4H polytype of SiC. Optional SiC polytypes include 3C, 6H, and 15R polytypes. Alternative materials for the substrate 102 may include sapphire (Al₂O₃), aluminum nitride (AlN), AlGaN, GaN, silicon (Si), gallium arsenide (GaAs), zinc oxide (ZnO), and indium phosphide (InP). The substrate 102 is generally between 300 micrometers and 500 micrometers thick.

A nucleation layer may be formed on a surface of the substrate 102 to provide an appropriate crystal structure transition between the SiC of the substrate 102 and the various epitaxial layers that are to be formed on the substrate 102. The nucleation layer may be a single layer or a series of layers. The nucleation layer is generally between 300 micrometers and 500 micrometers thick.

A channel layer 116 is formed on the nucleation layer. The channel layer 116 is formed by one or more epitaxial layers. For this example, the channel layer 116 may be GaN. However, the channel layer 116 may more generally be a Group III nitride such as GaN, AlXGa1-XN where 0≤X<1, indium gallium nitride (InGaN), aluminum indium gallium nitride (AlInGaN), or the like. The channel layer 116 may be undoped, or at least unintentionally doped, and may be grown to a thickness of greater than about 2 nm. In certain embodiments, the channel layer 116 may employ a multi-layer structure, such as a superlattice or alternating layers of different Group III-nitrides, such as GaN, AlGaN, or the like.

A barrier layer 118 is formed on the channel layer 116. The barrier layer 118 may have a bandgap that is greater than the bandgap of the underlying channel layer 116. Further, the barrier layer 118 may have a smaller electron affinity than the channel layer 116. In this illustrated embodiment, the barrier layer 118 is AlGaN. However, the barrier layer 118 may include AlGaN, AlInGaN, AlN, or various combinations of these layers. The barrier layer 118 is generally between 2 nm and 40 nm thick; however, the barrier layer 118 should not be so thick as to cause cracking or substantial defect formation therein. The barrier layer 118 may be either undoped, or at least unintentionally doped, or doped with an n-type dopant to a concentration less than about 1E19 cm⁻³. Notably, together, the channel layer 116 and the barrier layer 118 form a semiconductor body of the HEMT 100.

As shown in FIG. 1, a dielectric layer 106 is formed on a surface of the barrier layer 118 opposite the channel layer 116 and is etched using known etching techniques to the shape shown. In this embodiment, the dielectric layer 106 is silicon nitride (SiN). However, the dielectric layer 106 may be formed of another suitable dielectric such as, for example, silicon dioxide (SiO2), aluminum silicon nitride (AlSiN), silicon oxynitride (SiON), or the like. It will be understood that the terms “SixNy,” “SiN,” and “silicon nitride” are used herein interchangeably to refer to both stoichiometric and non-stoichiometric SiN. Other materials that may be used for the dielectric layer 106 include, for example, magnesium oxide, scandium oxide, aluminum oxide, and/or aluminum oxynitride. Furthermore, the dielectric layer 106 may be a single layer or may include multiple layers of uniform or non-uniform composition. The material of the dielectric layer 106 should be capable of withstanding relatively high temperatures, and should allow at least a portion to be removed without significantly damaging the underlying barrier layer 118.

In general, the dielectric layer 106 may provide a relatively high breakdown field strength and a relatively low interface trap density at the interface with an underlying Group III nitride layer such as the barrier layer 118. The dielectric layer 106 may have a high etch selectivity with respect to the material of the barrier layer 118, and may not be reactive to the material of the barrier layer 118. Moreover, the dielectric layer 106 may have a relatively low level of impurities therein. For example, the dielectric layer 106 may have a relatively low level of hydrogen and other impurities, including oxygen, carbon, fluorine, and chlorine. The dielectric layer 106 is generally between 80 nm and 200 nm thick.

As illustrated, the dielectric layer 106 is etched to expose surface portions 122A, 122B, 122C of the barrier layer 118. The area beneath the surface portion 122A corresponds to the drain region, and the area beneath the surface portion 122B corresponds to the source region. The areas beneath the surface portions 122A and 122B, which correspond to the drain and source regions, are subjected to a “shallow implant” to form respective shallow implant regions 124. The shallow implant regions 124 extend through the barrier layer 118 and at least partially into the channel layer 116. As such, the ions for the doping material come to rest in both the barrier layer 118 and at least the upper portion of the channel layer 116 beneath the surface portions 122A and 122B.

As used herein, the term “shallow implant” means that the implants are made directly into the barrier layer 118 with no substantive capping or protection layer over the surface portions 122A and 122B of the barrier layer 118 during implantation. The implanted ions of the doping material may be implanted such that a peak of the implant profile is located just below the interface between the channel layer 116 and the barrier layer 118 where a two-dimensional electron gas (2-DEG) plane is formed during operation and in which electron conductivity is modulated. While the doping concentrations may vary based on desired performance parameters, first exemplary doping conditions may provide shallow implant regions 124 with a peak doping concentration of 1×1018 cm⁻³ or greater and a straggle of 50 nanometers (nm) or less. For example, in some embodiments, the dose and energy of the implants may be selected to provide a peak doping concentration of about 5×1019 cm⁻³ and a straggle of about 30 nm. In order to form n-type shallow implant regions 124 in a nitride-based barrier layer 118, the implanted ions may include Si ions, sulfur ions, oxygen ions, or a combination thereof.

On the surface portion 122A, a drain contact 116 is formed. The drain contact 116 is an ohmic contact that cooperates with the shallow implant region 124 residing beneath the surface portion 122A to provide a low resistance connection to the drain region of the HEMT 100. Similarly, on the surface portion 122B, a source contact 110 is formed. The source contact 110 is an ohmic contact that cooperates with the shallow implant region 124 residing beneath the surface portion 122B to provide a low resistance connection to the source region of the HEMT 100. The source and drain regions connect with the opposite sides of the 2-DEG plane, which is just below the junction of the channel layer 116 and barrier layer 118.

As noted above, the dielectric layer 106 is also etched to expose the surface portion 122C of the barrier layer 118. The surface portion 122C resides between the surface portions 122A and 122B and corresponds to a gate region of the HEMT 100. A gate contact 112 is formed with one or more metallic layers over the surface portion 122C of the barrier layer 118. As illustrated, a portion of the gate contact 112 may be formed directly on the barrier layer 118, which itself may be formed from multiple epitaxial layers. Typically, an opening is etched through the dielectric layer 106 to expose the surface portion 122C. As illustrated, the gate contact 112 may have a portion that resides within the opening in contact with the surface portion 122C as well as portions that reside along the sidewalls of the opening and on an upper surface of the dielectric layer 106 on either side of the opening.

The gate contact 112 forms a non-ohmic contact with the barrier layer 118, and in particular may form a Schottky contact to the barrier layer 118.

A second dielectric layer 108 is formed over the dielectric layer 106 and the gate contact 112. A drain metallization layer 126 contacts the drain contact 116 through the second dielectric layer 108, and a source metallization layer 120 contacts the source contact 110 through the second dielectric layer 108. A field plate 122 is electrically connected to the source metallization layer 120 and extends over the gate contact 112. The field plate 122 reduces the negative impact of nearby electromagnetic fields on the gate contact 112 of the HEMT 100. The source metallization 120 connects to a backside source electrode 123 via a backside via 118 through the substrate 102 and the semiconductor body 104.

Under normal conditions, a channel is formed from the source contact 110 to the drain contact 116 through a channel that is formed by the 2DEG at the interface of the channel layer 116 and the barrier layer 118. To pinch off the channel and switch the device off, a negative voltage is applied to the gate contact 112, which depletes the 2DEG of carriers in a region beneath the gate contact 112. Applying a negative voltage to the gate contact 112 can undesirably cause a leakage current to flow into the gate contact 112, which reduces the performance of the HEMT 100.

Referring to FIG. 2, a gate contact 112 according to some embodiments is illustrated in more detail. In particular, the gate contact 112 includes a metal stack having a plurality of layers including a phonon scattering layer 112a that directly contacts the semiconductor body 104, a protection layer 112b on the phonon scattering layer 112a, and a contact layer 112c on the protection layer 112b.

The contact layer 112c may be a metal with a high conductivity and resistance to corrosion and oxidation, such as gold (Au), although other metals may be provided in the contact layer 112c in addition to or instead of gold.

The protection layer 112b separates the contact layer 112c from the phonon scattering layer 112a and obstructs the metals of those layers from alloying during fabrication. This obstructs the metal of the contact layer 112c from diffusing into the semiconductor body 104. The protection layer 112b may, for example, include titanium (Ti).

The phonon scattering layer 112a may include a metal having a work function in a range of about 4.5 eV to about 5.7 eV and a melting point in a range of about 1550° C. to about 3200° C. In some particular embodiments, the phonon scattering layer 112a comprises ruthenium (Ru). In some embodiments, the phonon scattering layer 112a comprises at least one of rhenium (Re), rhodium (Rh), niobium (Nb), palladium (Pd), osmium (Os), or iridium (Ir).

When the phonon scattering layer 112a comprises ruthenium, the phonon scattering layer 112a may additionally function as a diffusion barrier layer that protects the upper layers of the gate contact 112 against diffusion of impurities from the semiconductor body 104. Accordingly, when the phonon scattering layer 112a comprises ruthenium, an additional diffusion barrier layer may be avoided, which may reduce the time and/or expense of forming the gate contact 112.

In some embodiments, a thickness of the phonon scattering layer 112a is in a range of about 5 nm to about 35 nm, a thickness of the protection layer 112b is in a range of about 5 nm to about 40 nm, and a thickness of the contact layer 112c is greater than about 100 nm.

According to some embodiments, a ratio of thicknesses of the phonon scattering layer 112a and the protection layer 112b may be selected to reduce a film stress on the semiconductor body 104 and underlying substrate 102, as well as to improve adhesion of the phonon scattering layer 112a to the semiconductor body 104. This may improve both the mechanical robustness of the gate contact 112 as well as the temperature stability of the gate contact 112. In particular, to achieve good adhesion and temperature stability, the thicknesses of the phonon scattering layer 112a and the protection layer 112b may be about equal.

For example, in some embodiments, a ratio of a first thickness of the phonon scattering layer 112a to a second thickness of the protection layer 112b is about 1:1, in some embodiments about to 1:2, and in some embodiments about 1:3.

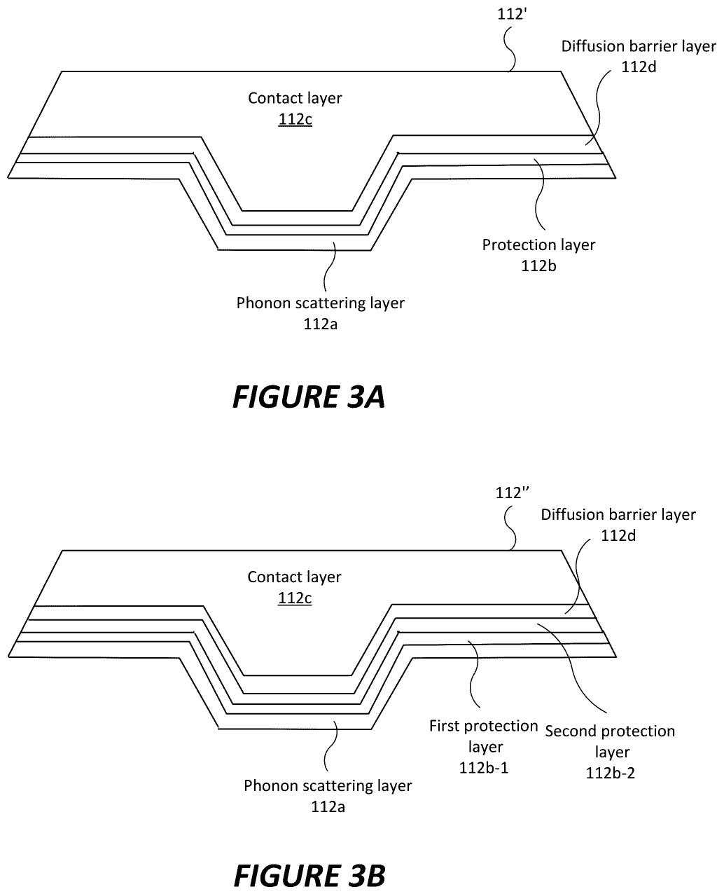

Referring to FIG. 3A, a gate contact 112′ according to further embodiments is illustrated. In particular, in the gate contact 112′, in addition to the phonon scattering layer 112a, the protection layer 112b and the contact layer 112c, a diffusion barrier layer 112d is provided between the protection layer 112b and the contact layer 112c. The diffusion barrier layer 112d may include palladium.

Referring to FIG. 3B, a gate contact 112″ according to further embodiments is illustrated. In particular, in the gate contact 112″, a first protection layer 112b-1 is formed on the phonon scattering layer 112a, and a second protection layer 112b-2 is formed on the first protection layer 112b-1. The first protection layer 112b-1 should be a good adhesion layer that is opposite stress to the phonon scattering layer 112a to counter the stress in the metal stack. For example, if the phonon scattering layer 112a has a tensile stress when formed on the semiconductor body 104, the first protection layer 112b-1 may have a compressive stress to offset the tensile stress of the phonon scattering layer 112a, and vice-versa.

The material and thickness of the first protection layer 112b-1 may be selected based on the thickness and stress of the phonon scattering layer 12a. In particular, the first protection layer 112b-1 may include Ti.

The second protection layer 112b-2 is a diffusion barrier that obstructs diffusion of gold from the contact layer 112c, and may comprise a material such as Pt. The second protection layer 112b-2 should be thick enough to form a continuous film, and may, for example, be greater than about 7.5 nm and less than about 30 nm.

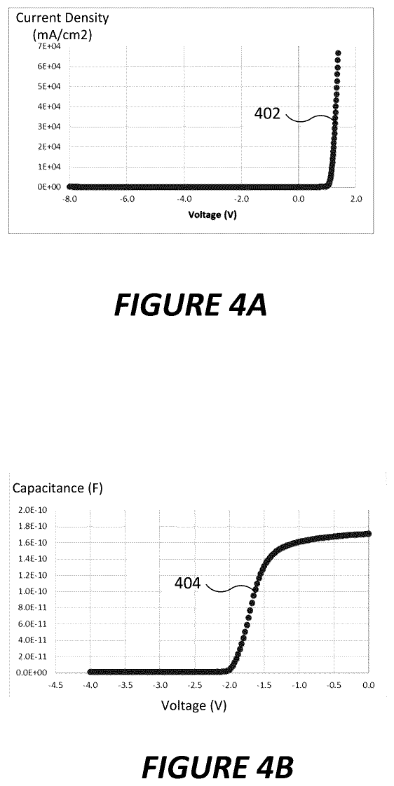

FIG. 4A illustrates the current characteristics 402 as a function of forward voltage and FIG. 4B illustrates capacitance values 404 as a function of forward voltage of a Schottky diode contact formed according to some embodiments described above. As shown in FIG. 4A, the contact shows a low off-state voltage and a turn-on voltage of about 1V. As evidenced by the capacitance-voltage sweep shown in FIG. 4B, the contact created a robust and clean interface with minimal interface traps and electronic defects.

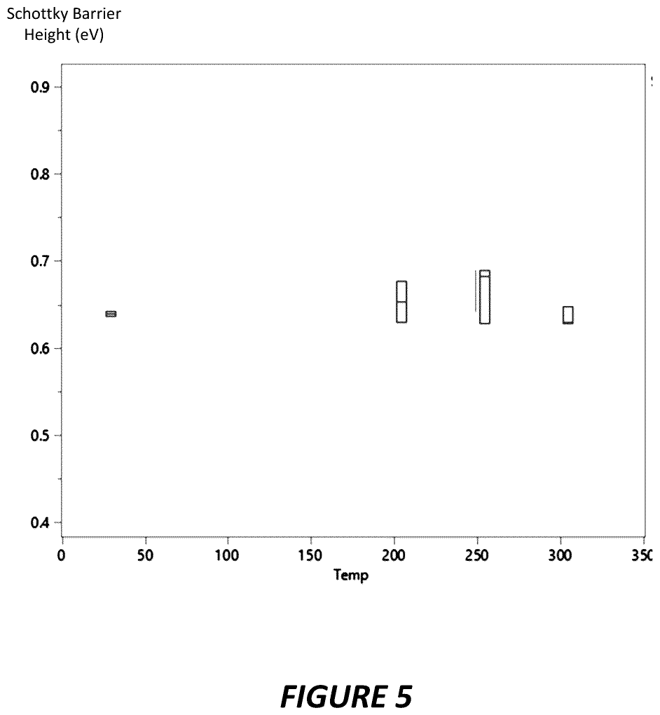

FIG. 5 is a graph of Schottky barrier height of a contact formed according to some embodiments at various process temperatures, including about 200C, 250C and 300C. As seen in in FIG. 5, the Schottky barrier height remains relatively stable across a range of process temperatures.

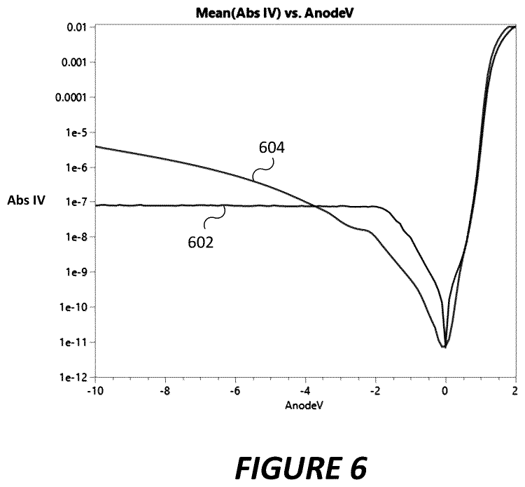

FIG. 6 illustrates reverse leakage current of a contact formed according to some embodiments (curve 602) compared to a conventional Ni-based contact (curve 604). As seen in FIG. 6, the device according to some embodiments exhibits lower reverse leakage current at anode voltages less than about −4V.

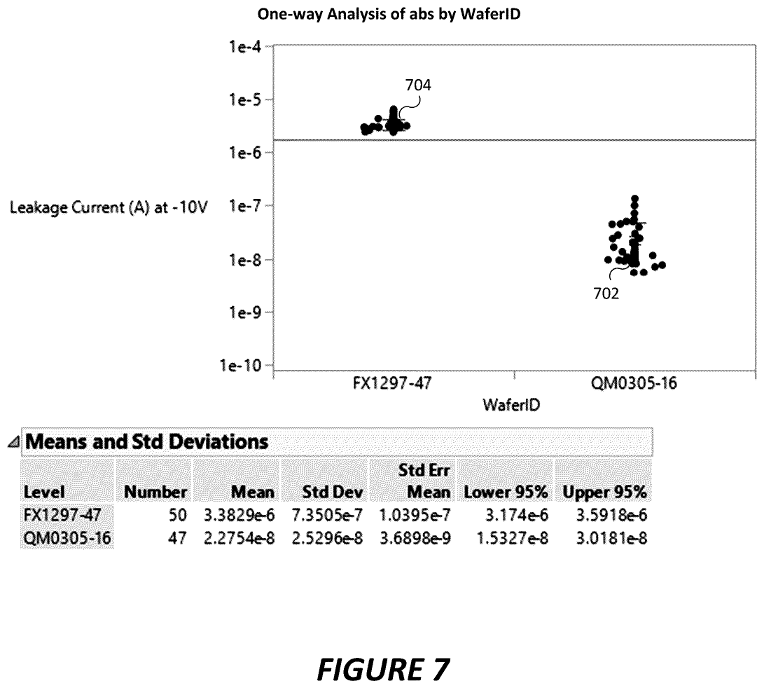

A plurality of conventional contacts and a plurality of contacts according to embodiments described herein were analyzed to measure leakage current characteristics at an anode voltage of −10V, and the results of such analysis are shown in FIG. 7. As shown therein, the conventional contacts 704 exhibited a leakage current between about 1E-5 and 1E-6 A with a mean of about 3.4E-6 A, while the contacts 702 according to embodiments described herein had leakage currents below about 1E-7 A with a mean of about 2.3E-8 A.

Transistor devices including contacts as described herein may be used in amplifiers that operate in a wide variety of different frequency bands. In some embodiments, the RF transistor amplifiers incorporating transistor devices as described herein may be configured to operate at frequencies greater than 1 GHz. In other embodiments, the RF transistor amplifiers may be configured to operate at frequencies greater than 2.5 GHZ. In still other embodiments, the RF transistor amplifiers may be configured to operate at frequencies greater than 3.1 GHZ. In yet additional embodiments, the RF transistor amplifiers may be configured to operate at frequencies greater than 5 GHz. In some embodiments, the RF transistor amplifiers may be configured to operate in at least one of the 2.5-2.7 GHz, 3.4-4.2 GHz, 5.1-5.8 GHZ, 12-18 GHZ, 18-27 GHZ, 27-40 GHz or 40-75 GHz frequency bands or sub-portions thereof.

Although embodiments of the inventive concepts have been discussed above with respect to HEMT devices, it will be understood that the inventive concepts described herein may be applied to other types of semiconductor devices, such as MOSFETs, DMOS transistors, and/or laterally diffused MOS (LDMOS) transistors.

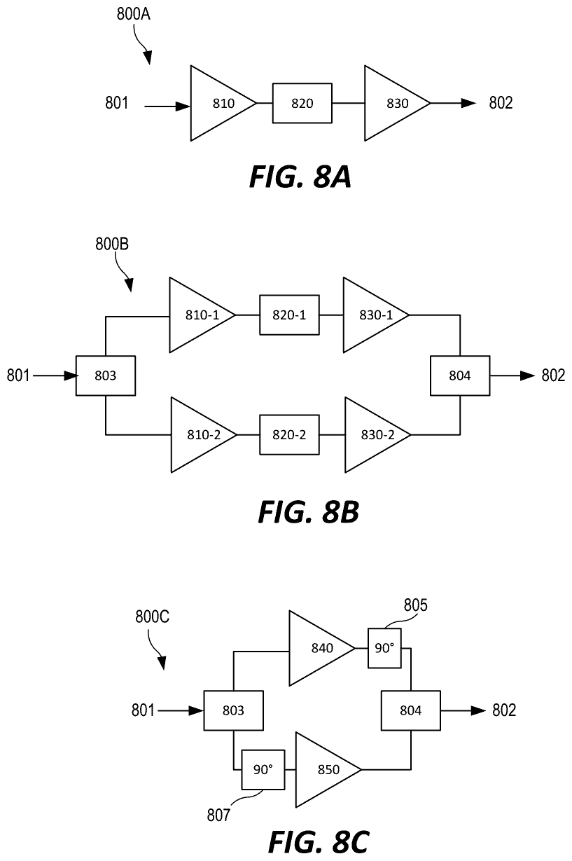

RF transistor amplifiers incorporating transistor devices described herein can be used in standalone RF transistor amplifiers and/or in multiple RF transistor amplifiers. Examples of how the RF transistor amplifiers according to some embodiments may be used in applications that include multiple amplifiers will be discussed with reference to FIGS. 8A-8C.

Referring to FIG. 8A, an RF transistor amplifier 800A is schematically illustrated that includes a pre-amplifier 810 and a main amplifier 830 that are electrically connected in series. As shown in FIG. 8A, RF transistor amplifier 800A includes an RF input 801, the pre-amplifier 810, an inter-stage impedance matching network 820, the main amplifier 830, and an RF output 802. The inter-stage impedance matching network 820 may include, for example, inductors and/or capacitors arranged in any appropriate configuration in order to form a circuit that improves the impedance match between the output of pre-amplifier 810 and the input of main amplifier 830. While not shown in FIG. 8A, RF transistor amplifier 800A may further include an input matching network that is interposed between RF input 801 and pre-amplifier 810, and/or an output matching network that is interposed between the main amplifier 830 and the RF output 802. The RF transistor amplifiers according to embodiments may be used to implement either or both of the pre-amplifier 810 and the main amplifier 830.

Referring to FIG. 8B, an RF transistor amplifier 800B is schematically illustrated that includes an RF input 801, a pair of pre-amplifiers 810-1, 810-2, a pair of inter-stage impedance matching networks 820-1, 820-2, a pair of main amplifiers 830-1, 830-2, and an RF output 802. A splitter 803 and a combiner 804 are also provided. Pre-amplifier 810-1 and main amplifier 830-1 (which are electrically connected in series) are arranged electrically in parallel with pre-amplifier 810-2 and main amplifier 830-2 (which are electrically connected in series). As with the RF transistor amplifier 800A of FIG. 8A, RF transistor amplifier 800B may further include an input matching network that is interposed between RF input 801 and pre-amplifiers 810-1, 810-2, and/or an output matching network that is interposed between the main amplifiers 830-1, 830-2 and the RF output 802.

As shown in FIG. 8C, the RF transistor amplifiers according to some embodiments may also be used to implement Doherty amplifiers. As is known in the art, a Doherty amplifier circuit includes first and second (or more) power-combined amplifiers. The first amplifier is referred to as the “main” or “carrier” amplifier and the second amplifier is referred to as the “peaking” amplifier. The two amplifiers may be biased differently. For example, the main amplifier may comprise a Class AB or a Class B amplifier while the peaking amplifier may be a Class C amplifier in one common Doherty amplifier implementation. The Doherty amplifier may operate more efficiently than balanced amplifiers when operating at power levels that are backed off from saturation. An RF signal input to a Doherty amplifier is split (e.g., using a quadrature coupler), and the outputs of the two amplifiers are combined. The main amplifier is configured to turn on first (i.e., at lower input power levels) and hence only the main amplifier will operate at lower power levels. As the input power level is increased towards saturation, the peaking amplifier turns on and the input RF signal is split between the main and peaking amplifiers.

As shown in FIG. 8C, the Doherty RF transistor amplifier 800C includes an RF input 801, an input splitter 803, a main amplifier 840, a peaking amplifier 850, an output combiner 804 and an RF output 802. The Doherty RF transistor amplifier 800C includes a 90° transformer 807 at the input of the peaking amplifier 850 and a 90° transformer 805 at the input of the main amplifier 840, and may optionally include input matching networks and/or an output matching networks (not shown). The main amplifier 840 and/or the peaking amplifier 850 may be implemented using any of the above-described RF transistor amplifiers according to embodiments.

The RF transistor amplifiers according to embodiments may be formed as discrete devices, or may be formed as part of a Monolithic Microwave Integrated Circuit (MMIC). A MMIC refers to an integrated circuit that operates on radio and/or microwave frequency signals in which all of the circuitry for a particular function is integrated into a single semiconductor chip. An example MMIC device is a transistor amplifier that includes associated matching circuits, feed networks and the like that are all implemented on a common substrate. MMIC transistor amplifiers typically include a plurality of unit cell HEMT transistors that are connected in parallel.

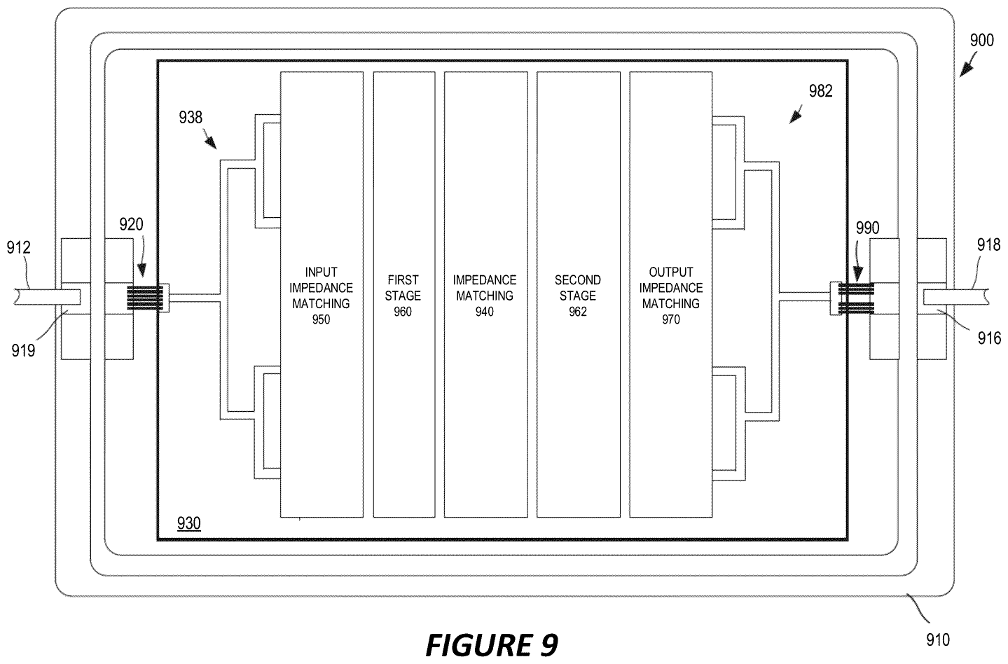

FIG. 9 is a plan view of a MMIC RF transistor amplifier 900 according to embodiments of the present inventive concepts. As shown in FIG. 9, the MMIC RF transistor amplifier 900 includes an integrated circuit chip 930 that is contained within a package 910. The package 910 may comprise a protective housing that surrounds and protects the integrated circuit chip 930. The package 910 may be formed of, for example, a ceramic material.

The package 910 includes an input lead 912 and an output lead 918. The input lead 912 may be mounted to an input lead pad 914 by, for example, soldering. One or more input bond wires 920 may electrically connect the input lead pad 914 to an input bond pad on the integrated circuit chip 930. The integrated circuit chip 930 includes an input feed network 938, an input impedance matching network 950, a first RF transistor amplifier stage 960, an intermediate impedance matching network 940, a second RF transistor amplifier stage 962, an output impedance matching stage 970, and an output feed network 982.

The package 910 further includes an output lead 918 that is connected to an output lead pad 916 by, for example, soldering. One or more output bond wires 990 may electrically connect the output lead pad 916 to an output bond pad on the integrated circuit chip 930. The first RF transistor amplifier stage 960 and/or the second RF transistor amplifier stage 962 may be implemented using any of the RF transistor amplifiers according to embodiments of the present inventive concepts.

The RF transistor amplifiers according to embodiments of the present inventive concepts may be designed to operate in a wide variety of different frequency bands. In some embodiments, these RF transistor amplifier dies may be configured to operate in at least one of the 0.6-2.7 GHZ, 3.4-4.2 GHZ, 5.1-5.8 GHz, 12-18 GHz, 18-27 GHZ, 27-40 GHz or 90-75 GHz frequency bands or sub-portions thereof. The techniques according to embodiments of the present inventive concepts may be particularly advantageous for RF transistor amplifiers that operate at frequencies of 10 GHz and higher.

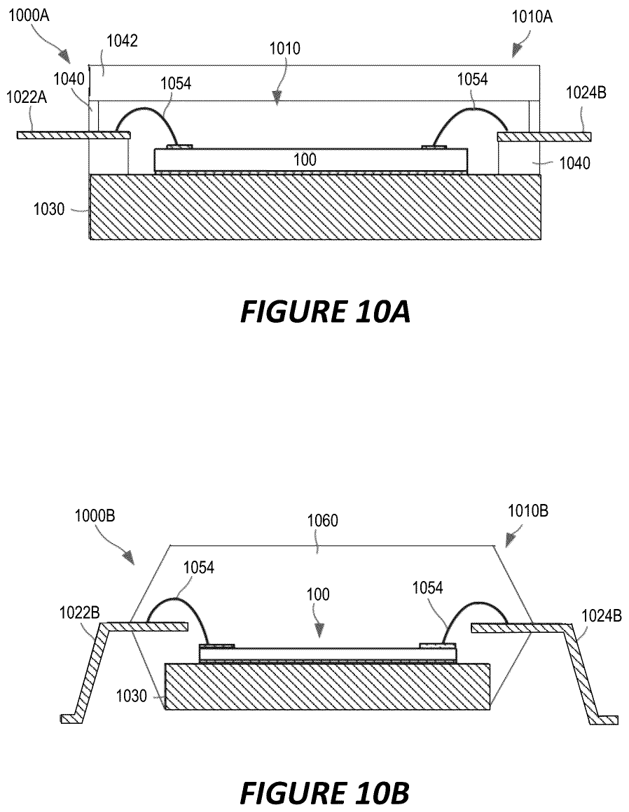

FIGS. 10A and 10B are schematic cross-sectional views illustrating several example transistor amplifier packages including RF transistor amplifier devices according to embodiments of the present inventive concepts.

FIG. 10A is a schematic side view of a packaged Group III nitride-based RF transistor amplifier 1000A. As shown in FIG. 10A, packaged RF transistor amplifier 1000A includes the RF transistor amplifier die 100 packaged in an open cavity package 1010A. The package 1010A includes metal gate leads 1022A, metal drain leads 1024A, a metal submount 1030, sidewalls 1040 and a lid 1042.

The submount 1030 may include materials configured to assist with the thermal management of the package 1000A. For example, the submount 1030 may include copper and/or molybdenum. In some embodiments, the submount 1030 may be composed of multiple layers and/or contain vias/interconnects. In an example embodiment, the submount 1030 may be a multilayer copper/molybdenum/copper metal flange that comprises a core molybdenum layer with copper cladding layers on either major surface thereof. In some embodiments, the submount 1030 may include a metal heat sink that is part of a lead frame or metal slug. The sidewalls 1040 and/or lid 1042 may be formed of or include an insulating material in some embodiments. For example, the sidewalls 1040 and/or lid 1042 may be formed of or include ceramic materials.

In some embodiments, the sidewalls 1040 and/or lid 1042 may be formed of, for example, Al2O3. The lid 1042 may be glued to the sidewalls 1040 using an epoxy glue. The sidewalls 1040 may be attached to the submount 1030 via, for example, braising. The gate lead 1022A and the drain lead 1024A may be configured to extend through the sidewalls 1040, though embodiments of the present inventive concepts are not limited thereto.

The RF transistor amplifier die 100 is mounted on the upper surface of the metal submount 1030 in an air-filled cavity 1012 defined by the metal submount 1030, the ceramic sidewalls 1040 and the ceramic lid 1042. The gate and drain terminals of RF transistor amplifier die 100 may be on the top side of the semiconductor layer structure 150, while the source terminal is on the bottom side of the semiconductor layer structure 150.

The gate lead 1022A may be connected to the gate terminal of RF transistor amplifier die 100 by one or more bond wires 1054. Similarly, the drain lead 1024A may be connected to the drain terminal of RF transistor amplifier die 100 by one or more bond wires 1054. The source terminal may be mounted on the metal submount 1030 using, for example, a conductive die attach material (not shown). The metal submount 1030 may provide the electrical connection to the source terminal 136 and may also serve as a heat dissipation structure that dissipates heat that is generated in the RF transistor amplifier die 100.

The heat is primarily generated in the upper portion of the RF transistor amplifier die 100 where relatively high current densities are generated in, for example, the channel regions of the unit cell transistors 102. This heat may be transferred though the source vias 146 and the semiconductor layer structure 150 to the source terminal and then to the metal submount 1030.

FIG. 10B is a schematic side view of another packaged Group III nitride based RF transistor amplifier 1000B. RF transistor amplifier 1000B differs from RF transistor amplifier 1000A in that it includes a different package 1010B. The package 1010B includes a metal submount 1030, as well as metal gate and drain leads 1022B, 1024B. RF transistor amplifier 1000B also includes a plastic overmold 1060 that at least partially surrounds the RF transistor amplifier die 100, the leads 1022B, 1024B, and the metal submount 1030.

Other components of RF transistor amplifier 1000B may be the same as the like-numbered components of RF transistor amplifier 1000A and hence further description thereof will be omitted. While embodiments of the present inventive concepts are described above with respect to gallium nitride based RF transistor amplifiers, it will be appreciated that embodiments of the inventive concepts are not limited thereto. For example, the transistors described above may also be used as power transistors in switching and other applications.

Embodiments of the present inventive concepts have been described above with reference to the accompanying drawings, in which embodiments of the inventive concepts are shown. The inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. Like numbers refer to like elements throughout. In the specification and the figures, two-part reference numbers (i.e., two numbers separated by a dash, such as 100-1) may be used to identify like elements. When such two-part reference numbers are employed, the full reference numeral may be used to refer to a specific instance of the element, while the first part of the reference numeral may be used to refer to the elements collectively.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present inventive concepts. As used herein, the term “and/or” includes any and all combinations of one or more of the associated listed items. The terminology used herein is for the purpose of describing particular embodiments only and is not intended to be limiting of the inventive concepts. As used herein, the terms “comprises,” “comprising,” “includes” and/or “including” specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Relative terms such as “below” or “above” or “upper” or “lower” or “horizontal” or “lateral” or “vertical” may be used herein to describe a relationship of one element, layer or region to another element, layer or region as illustrated in the figures.

Although embodiments of the inventive concepts have been described in considerable detail with reference to certain configurations thereof, other versions are possible. The field plates and gates can also have many different shapes and can be connected to the source contact in many different ways. Accordingly, the spirit and scope of the inventive concepts should not be limited to the specific embodiments described above.

1. A transistor device comprising:
a semiconductor body; and
a non-ohmic contact on the semiconductor body, wherein the non-ohmic contact comprises:
a phonon scattering layer on the semiconductor body, the phonon scattering layer having a work function in a range of about 4.5 eV to about 5.7 eV and a melting point in a range of about 1550° C. to about 3200° C.;
a protection layer on a surface of the phonon scattering layer opposite the semiconductor body; and
a contact layer on a surface of the protection layer opposite the phonon scattering layer.

2. The transistor device of claim 1, wherein the phonon scattering layer comprises ruthenium (Ru).

3. The transistor device of claim 1, wherein the phonon scattering layer comprises at least one of rhenium (Re), rhodium (Rh), niobium (Nb), palladium (Pd), osmium (Os), or iridium (Ir).

4. The transistor device of claim 1, wherein a thickness of the phonon scattering layer is in a range of about 5 nm to about 35 nm.

5. The transistor device of claim 1, wherein a thickness of the protection layer is in a range of about 5 nm to about 40 nm.

6. The transistor device of claim 1, wherein a thickness of the contact layer is greater than about 100 nm.

7. The transistor device of claim 1, wherein a ratio of a first thickness of the phonon scattering layer to a second thickness of the protection layer is about 1:1.

8. The transistor device of claim 1, wherein a ratio of a first thickness of the phonon scattering layer to a second thickness of the protection layer is about to 1:2.

9. The transistor device of claim 1, wherein a ratio of a first thickness of the phonon scattering layer to a second thickness of the protection layer is about 1:3.

10. The transistor device of claim 2, wherein a thickness of the phonon scattering layer is in a range of about 5 nm to about 35 nm, a thickness of the protection layer is in a range of about 5 nm to about 40 nm, and a thickness of the contact layer is greater than about 100 nm.

11. The transistor device of claim 1, wherein the semiconductor body comprises one or more Group III nitride epitaxial layers.

12. The transistor device of claim 11, wherein the one or more Group III nitride epitaxial layers comprises at least one of a gallium nitride layer and an aluminum gallium nitride layer.

13. The transistor device of claim 11, further comprising:
a silicon carbide substrate, wherein the semiconductor body is on a surface of the silicon carbide substrate.

14. The transistor device of claim 1, wherein the transistor device comprises a gallium nitride (GaN) based high-electron mobility transistor (HEMT).

15. The transistor device of claim 1, wherein the protection layer comprises titanium (Ti) and the contact layer comprises gold (Au).

16. The transistor device of claim 1, wherein the non-ohmic contact forms a Schottky junction with the semiconductor body.

17. A transistor device comprising:
a semiconductor body;
a gate electrode, a source electrode, and a drain electrode on the semiconductor body; and
a metal stack between the semiconductor body and at least a portion of the gate electrode, wherein the metal stack comprises:
a layer of ruthenium (Ru) on the semiconductor body;
a protection layer on a surface of the layer of ruthenium (Ru) opposite the semiconductor body;
a diffusion barrier layer on the surface of the protection layer opposite the layer of ruthenium (Ru); and
a contact layer on the surface of the diffusion barrier layer opposite the protection layer.

18. The transistor device of claim 17, wherein a thickness of the layer of ruthenium (Ru) is in a range of about 5 nm to 35 nm.

19. The transistor device of claim 17, wherein a thickness of the protection layer is in a range of about 5 nm to about 20 nm.

20. The transistor device of claim 17, wherein a thickness of the diffusion barrier layer is in a range of about 5 nm to about 20 nm

21. The transistor device of claim 17, wherein a thickness of the contact layer is greater than about 100 nm.

22. The transistor device of claim 17, wherein the protection layer comprises a first protection layer and a second protection layer, and a thickness of the layer of ruthenium (Ru) is about 5 nm, a thickness of the first protection layer is about 15 nm, a thickness of the second protection layer is about 10 nm, a thickness of the diffusion barrier layer is about 20 nm, and a thickness of the contact layer is greater than 100 nm.

23. The transistor device of claim 22, wherein the first protection layer comprises a material having a stress that is opposite a stress of the layer of ruthenium.

24. The transistor device of claim 22, wherein the first protection layer comprises titanium (Ti).

25. The transistor device of claim 22, wherein the second protective layer obstructs diffusion of atoms from the contact layer.

26. The transistor device of claim 17, wherein the semiconductor body comprises one or more Group III nitride epitaxial layers.

27. The transistor device of claim 26, wherein the one or more Group III nitride epitaxial layers comprises at least one of a gallium nitride layer and an aluminum gallium nitride layer.

28. The transistor device of claim 17, further comprising:
a silicon carbide substrate, wherein the semiconductor body is on a surface of the silicon carbide substrate.

29. The transistor device of claim 17, wherein the transistor device comprises a gallium-nitride (GaN) based high-electron mobility transistor HEMT.

30. The transistor device of claim 17, wherein the protection layer comprises titanium (Ti), the diffusion barrier layer comprises platinum (Pt) and the contact layer comprises gold (Au).
